(19) United States
(12) Patent Application Publication
(10) Pub. No.: US 2006/0030152 A1
(43) Pub. Date: Feb. 9, 2006

(54) Method of manufacturing substrate having recessed portions for microlenses and transmissive screen

(76) Inventors: Kazuto Yoshimura, Suwa (JP); Makoto Ishii, Chino (JP)

Correspondence Address: HARNESS, DICKEY & PIERCE, P.L.C., P.O. BOX 828, BLOOMFIELD HILLS, MI, 48303, US

(21) Appl. No.: 11/181,498

(22) Filed: Jul. 14, 2005

(30) Foreign Application Priority Data
Aug. 3, 2004 (JP) 2004-226829

(51) Int. Cl. H01L 21/302

(52) U.S. Cl. 438/689

(57) ABSTRACT

A method of manufacturing a substrate having recessed portions for microlenses, the substrate being provided with a plurality of recessed portions on a surface thereof and the microlenses being formed by supplying resin to each of the recessed portions, the method includes: forming an etching mask film; forming through holes in regions of the etching mask film where the recessed portions are formed by irradiating laser beams onto the regions and modifying the entire etching mask film by heating; and forming the recessed portions on the surface of the substrate by bringing an etchant into contact with the surface of the substrate exposed by the through holes.

### BACKGROUND OF THE INVENTION

1. Technical Field

The present invention relates to a method of forming a mold for manufacturing a microlens array used for a rear projection television or the like.

2. Related Art

Generally, as a method of manufacturing a convex microlens array used for a rear projection television or the like, a method has been known in which a glass substrate having recessed portions, serving as a mold for microlenses, is manufactured, the recessed portions of the glass substrate are filled with resin to be hardened, and the mold is then removed.

In the glass substrate, the plurality of recessed portions are formed by forming an etching mask film on the glass substrate, forming a plurality of pin holes thereon, dipping the glass substrate in an etchant, and allowing the etching to proceed isotropically (for example, see Japanese Unexamined Patent Application Publication No. 2000-258609).

A method of forming the pin holes on the etching mask film includes a method in which a resist layer having openings having shapes corresponding to shapes of the pin holes is formed and dry etching is then performed or a method in which laser beams are irradiated onto locations where the pin holes are formed to remove the etching mask film.

Further, when the recessed portions are formed through wet etching, a chromium oxide film and a chromium film, serving as etching mask films, are sequentially laminated on a surface of the glass substrate, so that it is possible to make the S/D ratio (ratio of a semi-diameter to a depth of the recessed portion) of the recessed portion have a value of substantially 1. In addition, by using the substrate having the recessed portions as the mold, it is possible to form high-performance microlenses having a large viewing angle.

Now, the related art will be described with reference to FIGS. 4 and 5. As shown in FIG. 4A, in order to approximate the S/D ratio of a recessed portion to a value of 1, first, a chromium oxide film 52 and a chromium film 54, functioning as etching mask films, are formed on a glass substrate 50. Subsequently, as shown in FIG. 4B, through holes are formed by irradiating laser beams onto locations where the recessed portions are formed or by forming a resist layer having a pattern corresponding to the recessed portions to perform etching (for example, dry etching using CF gas) at locations where the recessed portions are formed.

In a case in which the through holes are formed by etching, the etching mask film is not modified. As shown in FIG. 4B, even when the through holes are formed by laser irradiation, if the pitch between the through holes is large, it is not possible to modify the entire etching mask film (see FIG. 5). As a result, the chromium oxide film is modified into the chromium film only in the vicinities of the through holes. The modified region 58 is shown in the drawing.

FIG. 4C shows a wet etching process. A substrate 50 is formed with recessed portions 60 by bringing the substrate 50 into contact with an etchant. On the other hand, a region where the etching mask film is not deteriorated by heat has low resistance to the etchant, and accordingly corrodes. In addition, since, in this region, the chromium film is laminated on the chromium oxide film in a state in which the chromium film is not modified into the chromium oxide film, the chromium film and the chromium oxide film may be damaged due to their stresses or the films are likely to be removed from the substrate. Therefore, the etching mask film may be removed from the surface of the substrate before isotropic etching progresses sufficiently, so that flat portions 62 may remain between adjacent recessed portions.

When the microlens array is manufactured using the substrate as a mold, flat portions are formed between adjacent microlenses, so that the optical characteristics deteriorate.

Further, when the wet etching is performed, the etching mask film corrodes due to the etchant and the etchant flows, thus influencing the etching mask film. As a result, the etching mask film may be removed before the recessed portions are finished. Further, in a case in which the chromium oxide film and the chromium film are laminated, when the wet etching is performed, it is likely that the etching mask film will be damaged due to a compressive stress of the chromium oxide film and a tensile stress of the chromium film.

When the etching mask film is removed before the recessed portions are finished, isotropic etching around the through holes does not progress further, so that flat portions may be formed between adjacent recessed portions. As a result, even in the microlens array obtained by using the substrate as the mold, flat portions are formed between convex lenses, so that the optical characteristics deteriorate.

### SUMMARY

An advantage of the invention is that it provides a method of manufacturing a substrate having recessed portions for microlenses, in which an isotropic etching can be sufficiently performed by preventing an etching mask film from being removed or damaged at the time of wet etching. The substrate having recessed portions for microlenses, manufactured by such a method, has a plurality of recessed portions each having a substantially hemispherical shape and sharp tips are formed between adjacent recessed portions, so that a microlens array having excellent optical characteristics can be obtained by using the substrate as a mold.

According to an aspect of the invention, a method of manufacturing a substrate having recessed portions for microlenses includes: forming an etching mask film on a surface of the substrate; forming through holes in regions of the etching mask film where the recessed portions are formed by irradiating laser beams onto the regions and modifying the entire etching mask film by heat at a time of the laser machining; and forming the recessed portions on the surface of the substrate by bringing an etchant into contact with the surface of the substrate exposed by the through holes.

When the laser beams are irradiated, the through holes are formed at portions where temperatures reach a boiling point in the etching mask film. However, the etching mask film around the through holes also is modified due to the heat of the laser beams, so that the intensity or adhesiveness with respect to the substrate increases. As a result, even though the substrate is dipped into the etchant, it can be prevented that the etching mask film is corroded or removed from the substrate. Therefore, the isometric etching around the through holes progresses sufficiently, flat portions do not remain between adjacent recessed portions, and ‘tips’ are finely formed. Here, the modification of the etching mask film means oxidation mainly, but the invention is not limited thereto. That is, examples of the modification may include various modifications so long as it can increase the intensity of the etching mask film.

It is preferable that, during the irradiation of the laser beams, the laser beams be irradiated onto the entire etching mask film such that gaps do not exist between laser beam irradiation spots. Therefore, the entire etching mask film is modified. In addition, it is possible to effectively prevent the etching mask film from being removed or damaged during the wet etching process.

Further, it is preferable that, during the irradiation of the laser beams, laser beams each of which an intensity at respective irradiation spots has a Bessel function distribution be used. In order for the laser beams to have the intensity according to the Bessel function distribution, an axicon element may be used. Therefore, the etching mask film is heated over a wide area, so that the etching mask film can be effectively modified.

Furthermore, it is preferable that, during the irradiation of the laser beams, the laser beams be repeatedly irradiated in plural shots onto each region where the respective recessed portions are formed such that the entire etching mask film is modified by the heating. By irradiating the laser beams repeatedly, the heat can be transmitted over the entire etching mask film.

Moreover, preferably, the etching mask film is formed in two layers such that an etching mask film at a side of the substrate is a chromium oxide film and an etching mask film away from the substrate is a chromium film. Since the chromium film has higher absorptance of a laser beam than that of the chromium oxide film, the chromium film is formed on the substrate, so that the laser machining efficiency can increase. In addition, by irradiating the laser beams, the chromium film is modified into the chromium oxide film to increase the intensity thereof, and the recessed portions can be sufficiently formed without the etching mask film being damaged during the wet etching process.

When the chromium oxide film and the chromium film are laminated, it is preferable that a thickness of the chromium oxide film be in a range of from ¼ to ½ of a thickness of the chromium film or be ⅓ of the thickness of the chromium film. Although the chromium oxide film has a compressive stress and the chromium film has a tensile stress, the compressive stress and the tensile stress can be eliminated by adjusting the thickness of the film, so that it is possible to prevent the films from being damaged due to the individual stress.

According to another aspect of the invention, a transmissive screen includes a microlens array which is formed by using, as a mold, the substrate having recessed portions for microlenses manufactured by the above-mentioned method, filling recessed portions of the substrate with resin to be hardened, and detaching the substrate having recessed portions for microlenses from the resin materials. According to this aspect, since the transmissive screen is a high-performance screen having the microlens array which can be manufactured at a low cost and has a large viewing angle, the transmissive screen can be applied to a projector.

Further, according to a further aspect of the invention, a display device includes a microlens array which is formed by using, as a mold, the substrate having recessed portions for microlenses manufactured by the above-mentioned method, filling the recessed portions of the substrate with resin to be hardened, and detaching the substrate having recessed portions for microlenses from the resin. According to this aspect, the display device is a high-performance display device having the microlens array which can be manufactured at a low cost and has a large viewing angle.

According to the method of manufacturing the substrate having recessed portions for microlenses, the etching mask film is modified by the heating caused by the laser beam irradiation, thereby increasing the intensity of the etching mask film or adhesiveness with respect to the etching mask film. Thus, during the wet etching, the etching mask films can be prevented from being removed or modified. As a result, it is possible to progress the isotropic etching around the through holes sufficiently and to form sharp tips between the respective recessed portions. The microlens array which is formed by using, as a mold, the substrate having recessed portions for microlenses manufactured by the above-mentioned method can be used for a transmissive screen and various display devices, which have excellent optical characteristics.

### BRIEF DESCRIPTION OF THE DRAWINGS

The invention will be described with reference to the accompanying drawings, wherein like numbers reference like elements, and wherein:

FIG. 1 is an explanatory view illustrating a method of manufacturing a substrate having recessed portions for a micro array according to the invention;

FIG. 2 is an explanatory view illustrating a method of manufacturing a substrate having recessed portions for a micro array according to the invention;

FIG. 3 is a schematic diagram illustrating a rear projection television according to an embodiment of the invention;

FIG. 4 is an explanatory view illustrating a method of manufacturing a substrate having recessed portions for a micro array according to a related art; and

FIG. 5 is an explanatory view illustrating a method of manufacturing a substrate having recessed portions for a micro array according to the related art.

### DESCRIPTION OF THE EMBODIMENTS

Hereinafter, preferred embodiments of the invention will be described with reference to the accompanying drawings.

### First Embodiment

Next, a method of manufacturing a substrate having recessed portions for microlenses according to a first embodiment of the invention will be described while comparing it with the related art.

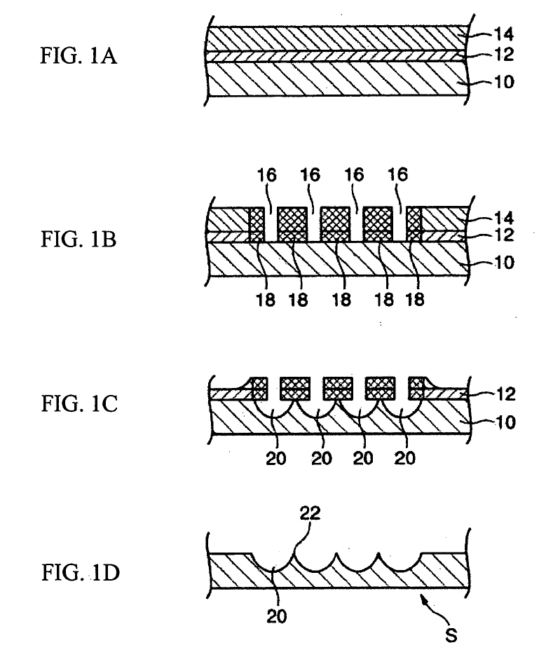

FIG. 1 is an explanatory view illustrating processes of the method of manufacturing the substrate according to the present embodiment. First, as shown in FIG. 1A, a chromium oxide film 12 and a chromium film 14 functioning as etching mask films are formed on a glass substrate 10. The chromium oxide film 12 and the chromium film 14 can be formed by using a sputtering method or a vapor deposition method. It is preferable that the thickness of the chromium oxide film 12 be ⅓ of that of the chromium film 14. For example, it is possible that the thickness of the chromium oxide film is 100 Å and the thickness of the chromium film is 300 Å.

In addition, an etching mask film may be formed on a rear surface of the substrate 10 (a surface where recessed portions are not formed). In this way, when the substrate 10 is dipped in the etchant, it is possible to prevent the rear surface of the substrate 10 from being etched.

Next, as shown in FIG. 1B, through holes 16 are formed in the chromium oxide film 12 and the chromium film 10 by irradiating laser beams. A gas laser, such as a C0₂ laser and an excimer laser, or a solid-state laser, such as a YAG laser, can be used.

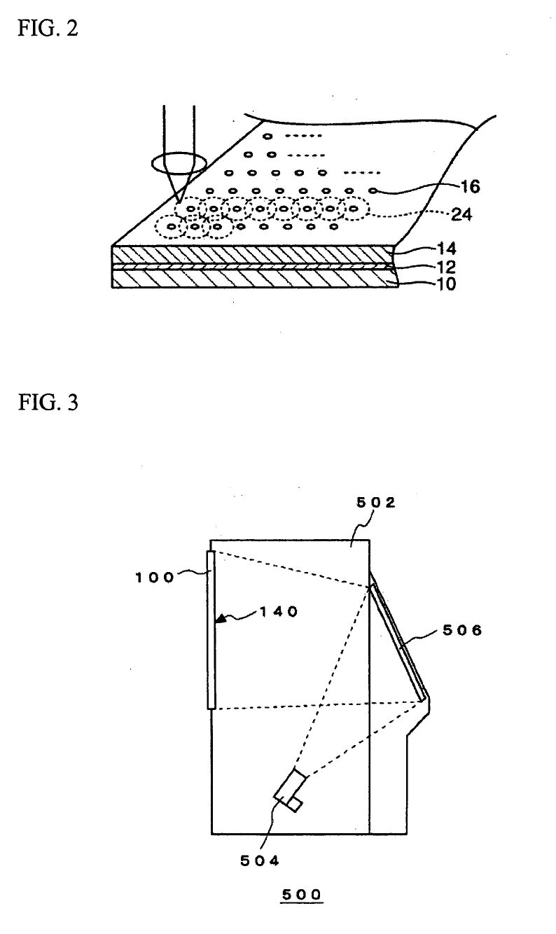

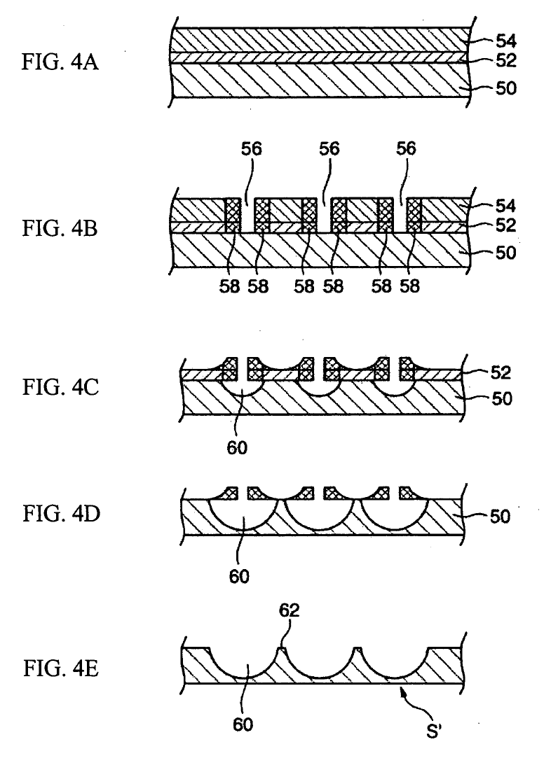

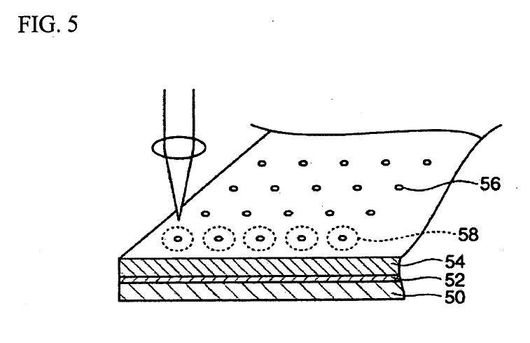

FIG. 2 shows an aspect in which laser beams are irradiated. Here, the through holes 16 are shown by solid lines, and irradiation spots 24 of the laser beams are shown by broken lines. As such, the laser beams are irradiated onto the chromium film 14 such that any point on the surface of the chromium film 14 is included in any one of the irradiation spots 24. As a result, the chromium film is effectively oxidized to become a chromium oxide film.

Further, it is preferably that the heat be applied over a wide area of the etching mask film by using an axicon element in which a beam mode of a laser focusing portion can be set to the distribution of the Bessel function. Further, preferably, when the laser beam is irradiated onto the respective through holes, the laser beam is repeatedly irradiated such that the heat is easily transmitted around the respective through holes. FIG. 1B shows regions 18 of the chromium film modified into the chromium oxide film.

FIG. 1C shows a wet etching process. The wet etching progresses isotropically, so that recessed portions 20 each having a substantially hemispherical shape are formed on the glass substrate 10. Although the etchant is used by suitably selecting a hydrofluoric acid etchant such as NH₄HF₂, it is preferable that an acid, such as sulfuric acid, be added. By adding the acid, it is possible to dissolve products of glass generated during etching, and to stabilize the etching rate.

It is difficult to corrode the regions 18, in which the chromium film is modified into the chromium oxide film by irradiating the laser beam, by etching. Further, all etching mask films composed of two layers become chromium oxide films, and thus a state in which they have the stresses in directions opposite to each other is removed. Therefore, it is difficult for the films to be damaged. As a result, even though the substrate is dipped in the etchant, the etching mask film remains on the substrate to form recessed portions, each having a substantially hemispherical shape, while the isotropic etching progresses sufficiently.

In this way, tips 22 having pointed ends are formed between the adjacent recessed portions 20, as shown in FIG. 1D. After the recessed portions are formed, the etching mask films can be removed through the wet etching by using, for example, an alkaline aqueous solution, thereby forming a substrate S having recessed portions for microlenses. When the etching mask film is also formed on the rear surface, the etching mask film can be removed at the same time.

The substrate, having recessed portions for microlenses formed in this way, is used as the mold, the recessed portions of the substrate are filled with resin to be hardened, and the substrate S is detached from the resin, and thus it is possible to form a microlens array on which convex microlenses are arranged. For a resin material, for example, an alkali resin and a polycarbonate resin can be used.

As described above, according to the present embodiment, by irradiating laser beams onto the entire etching mask films, the etching mask films in the vicinities of the through holes are modified by the heat, and the resistance to the etchant increases. Further, since all the etching mask films composed of two layers become the chromium oxide films, it is difficult for the films to be damaged due to the stresses in directions opposite to each other. Therefore, while the recessed portions are formed through the wet etching, the etching mask films remain on the substrate 10, so that the isotropic etching can progress sufficiently. In the substrate having recessed portions for microlenses obtained in this method, the tips are finely formed between the adjacent recessed portions. In addition, when the substrate is used as the mold, it is possible to obtain a microlens array having excellent optical characteristics.

Display Device

The microlens array, which is manufactured by the method of manufacturing the substrate according to the invention, can be used for various purposes for which the microlens array manufactured by the method according to the related art is used. For example, the microlens array according to the invention can be suitably used for a diffused plate, a black matrix screen, and a transmissive screen. Further, the microlens array according to the invention can be suitably used for a display device, such as a projector, using the transmissive screen. Examples of this display device may include a rear transmissive image display device (rear projection television).

FIG. 3 is a schematic diagram showing a rear transmissive image display device 500 having the microlens array manufactured by the method of manufacturing the substrate according to the invention. As shown in FIG. 3, in the display device 500, a case (cabinet) 502 includes a video projection device (projection cathode ray tube) 504 provided therein. Rear openings of the case 502 are covered with a mirror cover, and a reflecting mirror 506 is disposed in the mirror cover. On a front surface of the case 502, rectangular openings are formed, and the case includes a microlens array 100 whose lens forming surface 140 is disposed toward the light incident side.

Further, the substrate S having recessed portions for microlenses according to the invention can be used as a microlens substrate in such a manner that the recessed portions of the substrate are filled with resin to be hardened and the resin and the substrate are integrally formed. This microlens substrate can be used as a counter substrate for liquid crystal projector, for example.

### EXAMPLE 1

First, a chromium oxide film, serving as an etching mask film, having a thickness of 100 Å was formed on a glass substrate and a chromium film having a thickness of 300 Å was laminated thereon.

Next, laser beams were irradiated onto the chromium oxide film and the chromium film to form through holes, and the surface of the substrate was exposed. When the laser beams were irradiated, an excimer laser having a wavelength of 248 nm and a power density of 1.0 J/cm² was used, thereby forming through holes each having a diameter of 2.0 μm.

At that time, the pitch between the through holes was set to 72 μm×54 μm, the laser machining conditions were adjusted such that a modified region of the etching mask film at a time of forming any through hole overlapped a modified region of the etching mask film at a time of forming an adjacent through hole, the laser beams were irradiated onto the entire etching mask film, and the films were modified by the heat.

Next, as an etchant, an aqueous solution including 4% of NH₄HF₂ and 4% of H₂SO₄ was prepared, and the glass substrate on which the etching mask film had been formed was dipped in the aqueous solution. By adding sulfuric acid, it was possible to dissolve products of glass generated during etching, and to stabilize the etching rate.

In this case, the etching mask film remained on the substrate without being damaged until the isotropic etching progressed sufficiently, the recessed portions each having a substantially hemispheric shape were formed, and the tips having pointed ends were formed between the adjacent recessed portions.

On the other hand, according to a comparative example, the pitch between through holes was set to 144 μm×108 μm and the recessed portions were formed according to the same method as in the above-mentioned Example 1. In this case, the etching mask film was damaged before the recessed portions were sufficiently formed, and thus flat portions were formed between adjacent recessed portions.

Therefore, it can be apprehended that when the entire film is modified due to the heat caused by the laser beam irradiation, the recessed portions are suitably formed without the etching mask film being damaged, and when the etching mask film is not modified only in vicinities of the through holes, it is likely that the etching mask film is damaged during the process.

What is claimed is:

1. A method of manufacturing a substrate having recessed portions for microlenses, the substrate being provided with a plurality of recessed portions on a surface thereof and the microlenses being formed by supplying resin to each of the recessed portions, the method comprising:
forming an etching mask film;
forming through holes in regions of the etching mask film where the recessed portions are formed by irradiating laser beams onto the regions and modifying the entire etching mask film by heating; and
forming the recessed portions on the surface of the substrate by bringing an etchant into contact with the surface of the substrate exposed by the through holes.

2. The method of manufacturing a substrate having recessed portions for microlenses according to claim 1,
wherein, during the irradiation of the laser beams, the laser beams are irradiated onto the entire surface of the etching mask film without a gap.

3. The method of manufacturing a substrate having recessed portions for microlenses according to claim 1,
wherein, during the irradiation of the laser beams, laser beams each of which an intensity at respective irradiation spots has a Bessel function distribution are used.

4. The method of manufacturing a substrate having recessed portions for microlenses according to claim 1,
wherein, during the irradiation of the laser beams, the laser beams are irradiated in plural shots onto the regions where the respective recessed portions are formed, such that the entire etching mask film is modified by the heating.

5. The method of manufacturing a substrate having recessed portions for microlenses according to claim 1,
wherein the etching mask film is formed in two layers, the two layers being a chromium oxide film and a chromium film sequentially formed on the substrate.

6. The method of manufacturing a substrate having recessed portions for microlenses according to claim 5,
wherein the chromium oxide film has a thickness within a range of ¼ to ½ of a thickness of the chromium film.

7. A transmissive screen comprising:
a microlens array which is formed by using, as a mold, the substrate having recessed portions for microlenses manufactured by the method according to claim 1, filling recessed portions of the substrate with resin to be hardened, and detaching the substrate having recessed portions for microlenses from the resin.

8. A projector comprising the transmissive screen according to claim 7.

9. A display device comprising:
a microlens array which is formed by using, as a mold, the substrate having recessed portions for microlenses manufactured by the method according to claim 1, filling the recessed portions of the substrate with resin to be hardened, and detaching the substrate having recessed portions for microlenses from the resin.
